(19) United States
(12) Patent Application Publication
(10) Pub. No.: US 2014/0102616 A1
(43) Pub. Date: Apr. 17, 2014

(54) METHOD OF DIE BONDING AND APPARATUS THEREOF

(71) Applicant: INDUSTRIAL TECHNOLOGY RESEARCH INSTITUTE, Hsin-chu (TW)

(72) Inventors: Weng-Jung LU, Hsinchu City (TW); Wen-Hsien WU, Tainan City (TW); Chun-Hsien SU, Hsinchu City (TW)

(73) Assignee: INDUSTRIAL TECHNOLOGY RESEARCH INSTITUTE, Hsin-chu (TW)

(21) Appl. No.: 13/677,478

(22) Filed: Nov. 15, 2012

(30) Foreign Application Priority Data
Oct. 12, 2012 (TW) 101137739

(51) Int. Cl. H05K 13/04

(52) U.S. Cl. CPC H05K 13/046
USPC 156/64; 156/322; 156/498; 156/378

(57) ABSTRACT

A method of die bonding, the method has steps of: heating a substrate to a predetermined temperature; sucking at least one die, the at least one die with a base temperature, the base temperature being less than the predetermined temperature; the at least one die bonding on the substrate; cooling the substrate with the bonded die; and moving the substrate with the bonded die to a loading and unloading position, heating another substrate to a predetermined temperature, and repeating the said steps.

### CROSS REFERENCE TO RELATED APPLICATION

The present application is based on, and claims priority from, Taiwan (International) Application Serial Number 101137739, filed on Oct. 12, 2012, the disclosure of which is hereby incorporated by reference herein in its entirety.

### TECHNICAL FIELD

The present disclosure relates to a die bonding method and apparatus, and more particularly, to a die bonding method and apparatus for die preheating and bonding operations.

### BACKGROUND

With rapid advance of technology, the use of photonic devices is becoming more and more common in our daily life. For instance, light emitting diode (LED), which is well-known to be the most representative of all the photonic device, is considered to be the light source of next generation for replacing the conventional light sources, such as fluorescent lamps and halogen lamps.

Generally, the process for manufacturing a common photonic device starts from placing a die of a substrate so as to be bonded thereto. In the operation for placing dies on a substrate, first dies are picked and taken out of a die supplier by a pick-and-place device and then to be temporarily placed on a middle station where the dies can be picked by another pick-and-place device and moved out of the middle station so as to be place on a substrate. Since before a die can be bonded to a substrate, it can be picked up and temporarily placed on a process station for more than once, and moreover, since generally the conventional photonic device manufacturing process is performed using a single die bonder and a unit processing platform, all those current manufacturing processes for photonic devices are disadvantageous in their long process time and complex production procedures.

### SUMMARY

In an embodiment, the present disclosure provides a die bonding method, which comprises the steps of:
heating a substrate to a predetermined temperature;
picking up at least one die;
placing and bonding the at least one die to the substrate;
cooling the substrate with the bonded die; and
moving the substrate with the bonded die to a loading/unloading position while enabling another substrate to be heated to the predetermined temperature for repeating the aforesaid steps.

In another embodiment, the present disclosure provides a die bonding apparatus, which comprises:
a platform;
a die supplier, disposed at an end of the platform;
a heating/cooling unit, disposed at another end of the platform other than the one corresponding to the die supplier;
a die bonder, disposed on top of the platform while allowing the same to move between the die supplier and the heating/cooling unit.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a three-dimensional view of a die bonding apparatus according to the present disclosure.

FIG. 2 is a three-dimensional view of a die supplier according to the present disclosure.

FIG. 3 is a three-dimensional view of a temperature control module according to the present disclosure.

FIG. 4 is a three-dimensional view of a pick-and-place module according to the present disclosure.

FIG. 5 is a schematic diagram showing the relative movement between the die supplier and the pick-and-place module in the present disclosure.

FIG. 6 is a schematic diagram showing the relative movement between the die supplier, the pick-and-place module and the heating/cooling unit in the present disclosure.

FIG. 7 is a schematic diagram showing the relative movement between the pick-and-place module and the heating/cooling unit in the present disclosure.

FIG. 8 is a flow chart showing the steps performed in a die bonding method according to the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

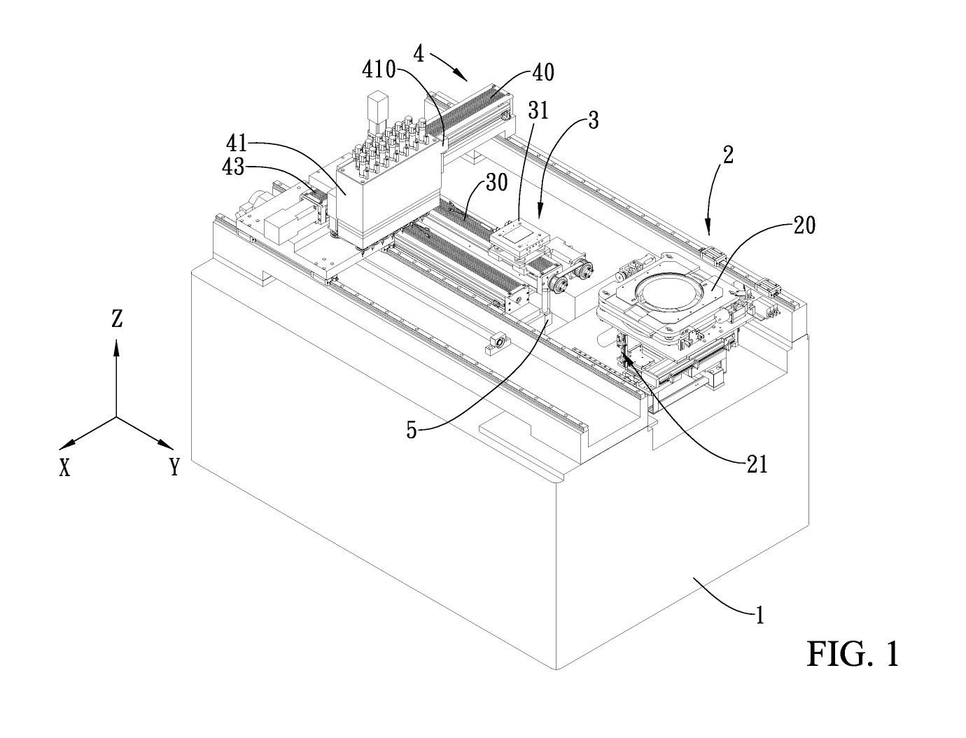

Please refer to FIG. 1, which a three-dimensional view of a die bonding apparatus according to the present disclosure. As shown in FIG. 1, a die bonding apparatus is disclosed, which comprises: a platform 1, a die supplier 2, a heating/cooling unit 3, a die bonder 4, a first image capturing module 410 and a second image capturing module 5.

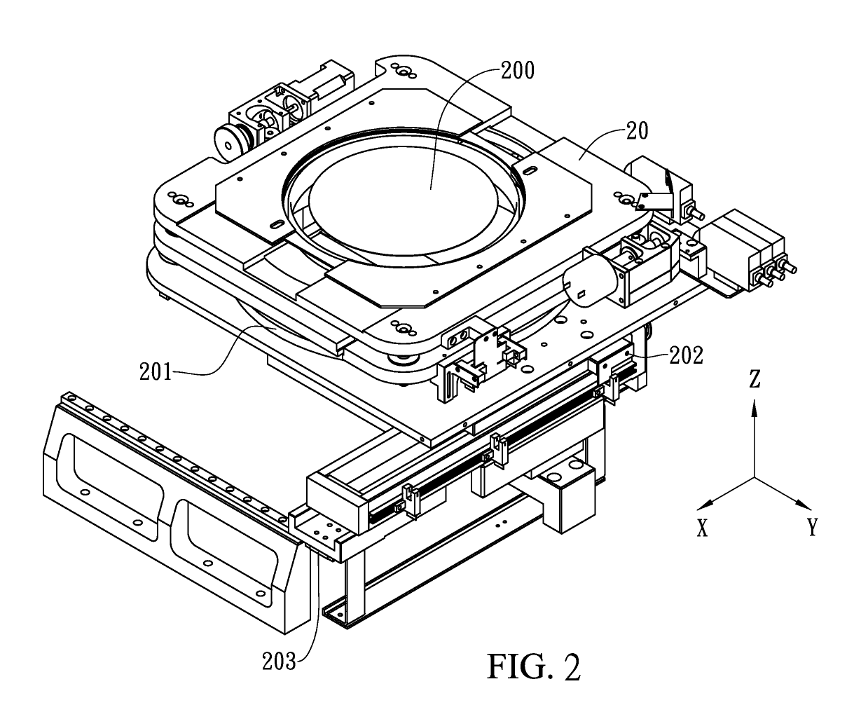

As shown in FIG. 1 and FIG. 2, the die supplier 2 is arranged at an end of the platform 2 and is configured with a workbench 20 and a die ejection module 21. Moreover, the workbench 20 is configured with a carrier 200, a rotation module 201, an X-axis mover 202 and a Y-axis mover 203 in a manner that the carrier 200 is mounted to a top end of the rotation module 201 for allowing the rotation module 2010 to rotate the carrier 200 by an angle. In an embodiment, the angle can be ranged between 0 degree to 360 degrees, but is not limited thereby. In addition, the X-axis mover 202 and the Y-axis mover 203 are mounted to a bottom end of the carrier 200. Operationally, the X-axis mover 202 is used for driving the carrier 200 to move in an X-axis direction, while the Y-axis mover 203 is used for driving the carrier 200 to move in a Y-axis direction. As shown in FIG. 2, the X-axis direction is perpendicular to the Y-axis direction. In addition, the die ejection module 21 mounted to a bottom end of the carrier 200.

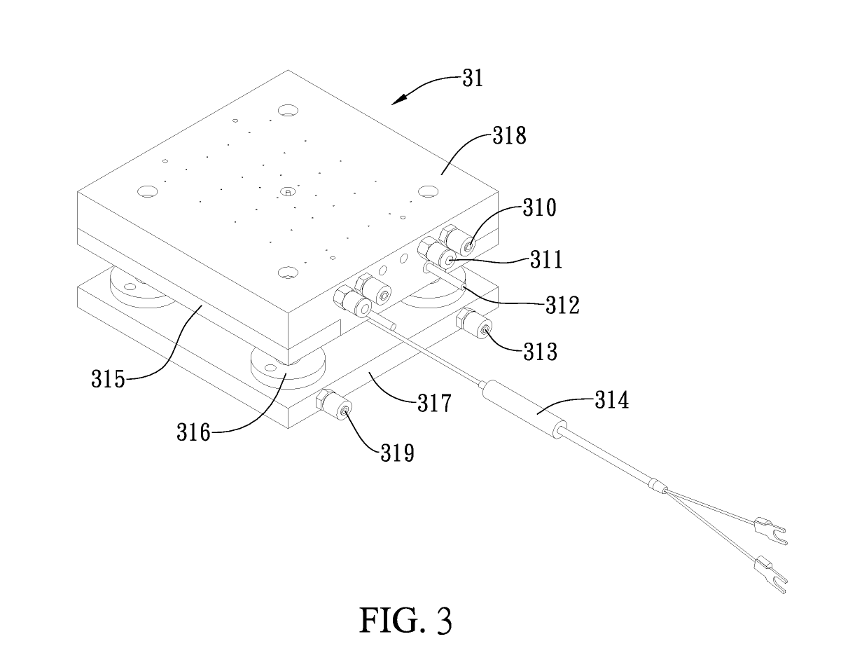

As shown in FIG. 1 and FIG. 3, the heating/cooling unit 3 is disposed at another end of the platform 1 other than the one corresponding to the die supplier 2, and in this embodiment, the heating/cooling unit 3 is configured with at least one temperature control module 31 and at least one Y-axis move module 30 in a manner that the at least one temperature control module 31 is mounted to the at least one Y-axis move module 30 for enabling the at least one temperature control module 31 to be driven by the Y-axis move module 30 so as to move in a Y-axis direction. In this embodiment, there are two temperature control modules 31 and two Y-axis move modules 30, and each of the two temperature control modules 31 is further configured with a support panel 318, a constant temperature plate 317, at least one bracket 316 and a temperature sensor 314.

As shown in FIG. 3, the support panel 318 is further configured with at least one cooling fluid inflowing tube 311, at least one cooling fluid discharging tube 310, at least one heating tube 312 and a heat insulation plate 315. In this embodiment, each of the one cooling fluid inflowing tube 311 is used for guiding a cooling fluid to flow inside the support panel 318 for cooling the same; and each of the at least one cooling fluid discharging tube 310 is used for guiding the cooling fluid to flow out of the support panel 308. In addition, each of the heating tube 312 can be an electric heater that is used for heating the support panel 318 to a predetermined temperature. Moreover, the heat insulation plate 315 is attached to the bottom of the support panel 318 for preventing any components that are arranged on the support panel 318 from being affected by the heat from the support panel 318.

The bracket 316 is arranged at a position between the support panel 318 and the constant temperature plate 317 so as to consequently enclose and form a space for allowing the temperature sensor 314 to be arranged therein.

The constant temperature plate 317 is configured with a thermostatic liquid inflowing tube313 and a thermostatic liquid discharging tube 319. Operationally, the thermostatic liquid inflowing tube313 is provided for guiding a thermostatic liquid to flow inside the constant temperature plate 317 for maintaining the temperature control module 31 at a specific temperature; while the thermostatic liquid discharging tube 319 is used for guiding the thermostatic liquid to flow out the constant temperature plate 317.

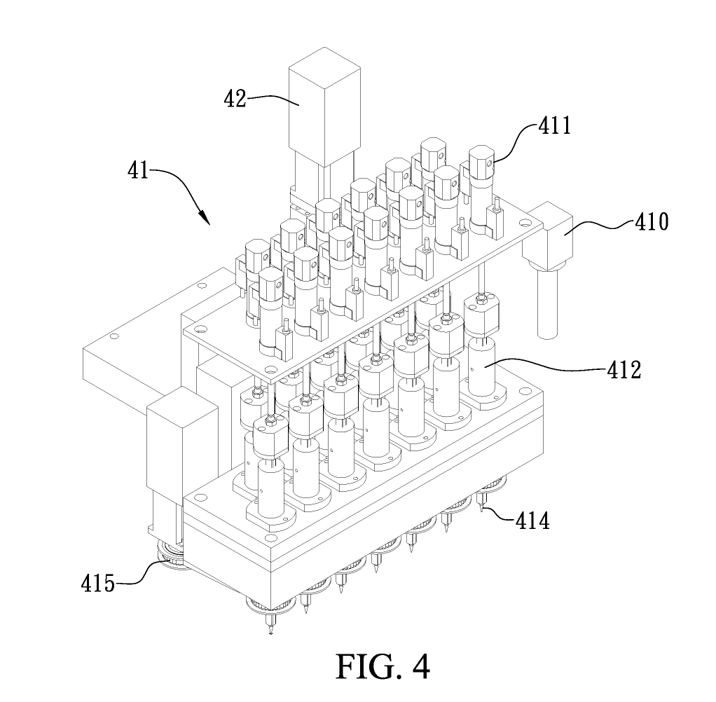

As shown in FIG. 1 and FIG. 4, the die bonder 4 is disposed on top of the platform 1 while allowing the same to move between the die supplier 2 and the heating/cooling unit 3. In addition, the die bonder 4 is further configured with a Y-axis move module 40, a pick-and-place module 41, a Z-axis alignment module 42, and an X-axis move module 43. In addition, the Y-axis move module 40 is mounted to the two sides of the platform 1 for allowing the Y-axis move module 40 to drive the pick-and-place module 41 to move in a Y-axis direction.

The pick-and-place module 41 is further configured with: a plurality of suction nozzles 414, a plurality of angular alignment elements 415, a plurality of vacuum adapters 412 and a plurality of adjustable pressurizers 411 in a manner that the plural suction nozzles 414 are arranged coupling to the plural angular alignment elements 415 in respective, and the plural vacuum adapters 412 are arranged coupling to the plural suction nozzles 414 in respective while allowing the plural pressurizers 411 to couple respectively to the plural vacuum adapters 412. Operationally, each angular alignment elements 415 is used for enabling its corresponding suction nozzle 414 to rotate by a specific angle, whereas the specific angle can be any angle ranged between 0 degree to 360 degrees, but is not limited thereby. Moreover, by the use of the vacuum adapter 412, each suction nozzle 414 is connected to its corresponding adjustable pressurizer 411 for enabling the suction nozzle 414 to have a sufficient sucking power or to exert a sufficient pressure.

As the plural suction nozzles 411 are connected to the plural adjustable pressurizers 411 through the connections of their corresponding vacuum adapters 412 the adjustable pressurizers 411 can be used for adjusting the pressing forces of the plural suction nozzles. Thereby, the adjustable pressurizers 411 can substantially be used for adjusting the duration of a die bond period.

The Z-axis alignment module 42 is coupled to the pick-and-place module 41 so as to be used for driving the pick-and-place module 41 to move in a Z-axis direction, whereas the Z-axis direction is perpendicular to the X-axis and Y-axis directions.

The X-axis move module 43 is coupled to the pick-and-place module 41 and the Y-axis move module 40, by that the pick-and-place module 41 can be driven to move in an X-axis direction by the X-axis move module 43.

In addition, the first image capturing module 410 is mounted on the pick-and-place module 41, by that the first image capturing module 410 can be brought along to move with the movement of the pick-and-place module 41. Moreover, the second image capturing module 5 is arranged above the platform 1 at a position between the die supplier 2 and the heating/cooling unit 3.

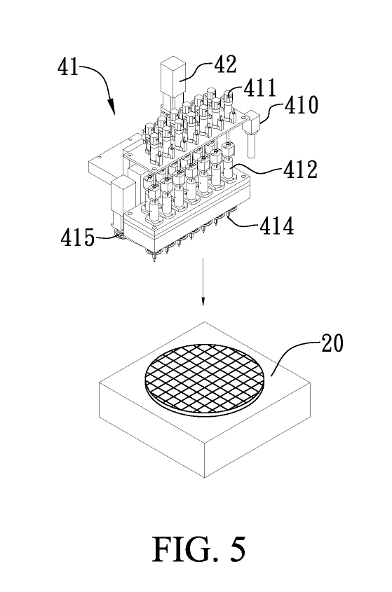

As shown in FIG. 1 and FIG. 5, by the cooperation of the X-axis move module 43, Z-axis alignment module 42, and the Y-axis move module 40, the pick-and-place module 41 can be moved and placed on top of the workbench 20. As soon as the pick-and-place module 41 is moved to the top of the dies that are to be processed, the die will be pushed and ejected by the die ejection module 21 for allowing the plural suction nozzles 414 to suck and fetch their corresponding dies sequentially.

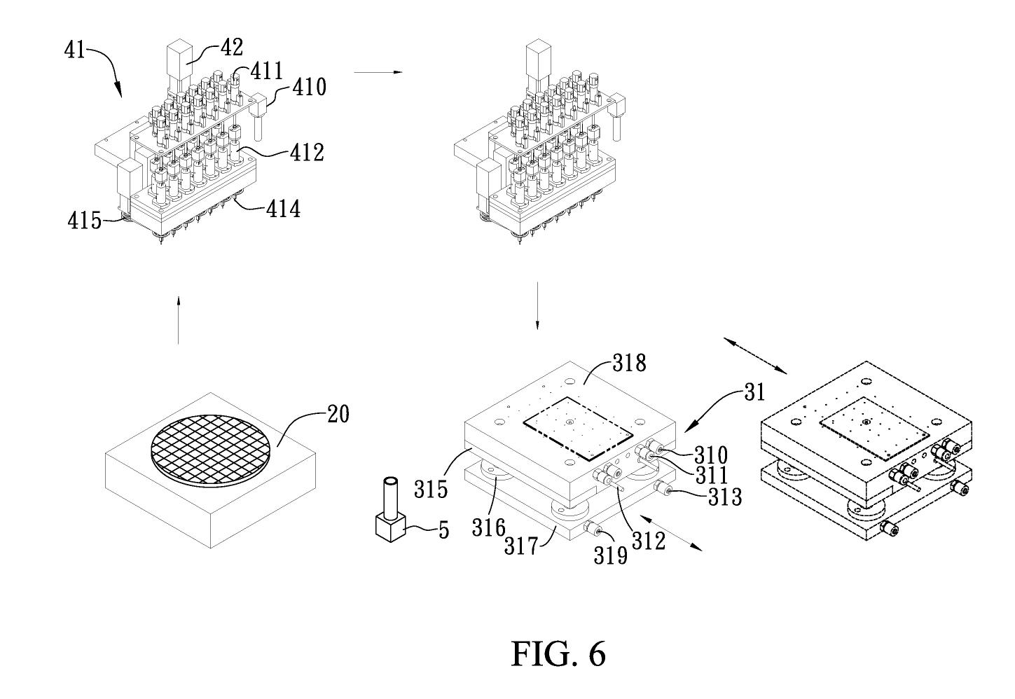

Please refer to FIG. 6, which is a schematic diagram showing the relative movement between the die supplier, the pick-and-place module and the heating/cooling unit in the present disclosure. As shown in FIG. 6, after picking up the dies, the pick-and-place module 41 is driven to move along the Z-axis direction, Y-axis direction and X-axis direction to a position above the temperature control module 31, at which a substrate had already been preheated to the predetermined temperature. Nevertheless, during the moving of the pick-and-place module 41, the second image capturing module 5 is enabled to capture images relating to the bottom view of the dies held in their respectively suction nozzles 414, and thereby, if there is any of those dies that is not aligned correctly, its corresponding angular alignment elements 415 will be activated for adjusting the positioning of the die by rotating the relating suction nozzle 414 by an angle.

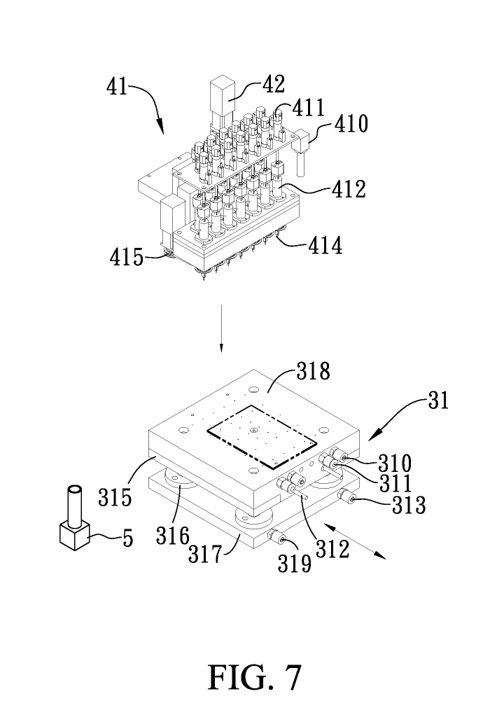

Please refer to FIG. 7, which is a schematic diagram showing the relative movement between the pick-and-place module and the heating/cooling unit in the present disclosure. After the pick-and-place module 41 is being positioned directly above the heated substrate, the pick-and-place module 41 will enable the dies that are hold in the suction nozzles 414 to be bonded on the substrate by exerting a downward pushing force on the dies.

As shown in FIG. 6, after bonding, the temperature control module 31 will be moved to a loading/unloading position, and during the moving of the temperature control module 31 to the loading/unloading position, the temperature control module 31 is activated to cool down the substrate with the bonded dies while the same time enabling another temperature control module 31 with another preheated substrate to be moved to the position under the pick-and-place module 41 for another die bonding process.

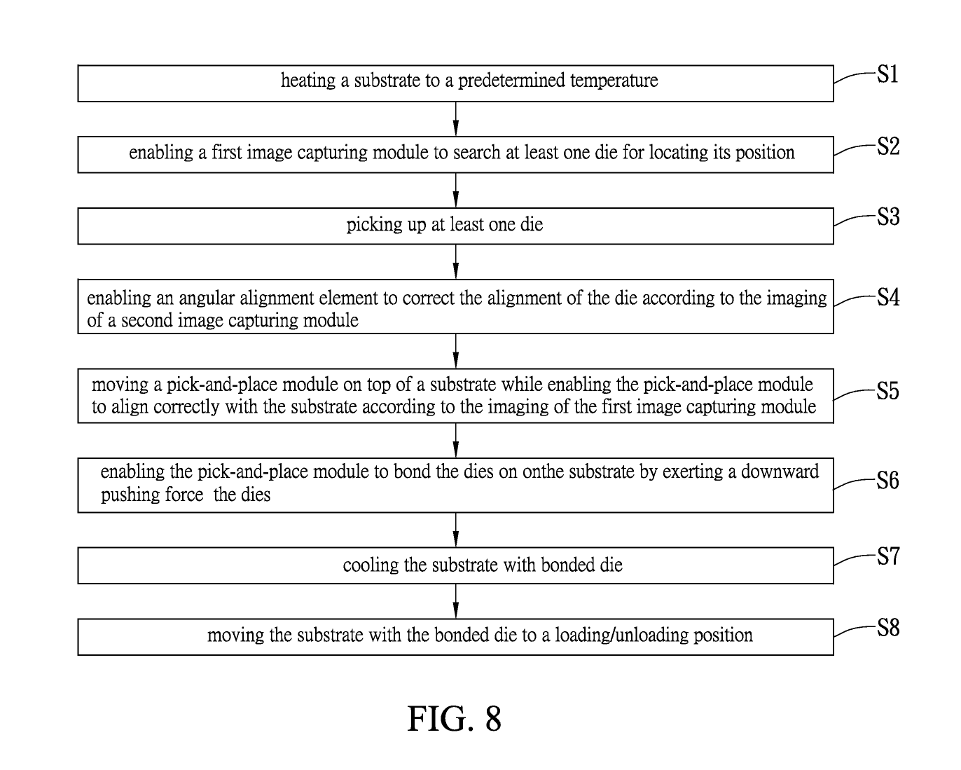

Please refer to FIG. 8, which is a flow chart showing the steps performed in a die bonding method according to the present disclosure. The die bonding method disclosed in the embodiment of FIG. 8 comprises the following steps:
S1: enabling at least one temperature control module 31 to heat a substrate to a first predetermined temperature, whereas the first predetermined temperature can be a melt point of a solder. In this embodiment, the melt point can be any temperature between 85° C. and 200° C., but is not limited thereby. As shown in FIG. 1 and FIG. 3, operationally when the support panel 318 is being heated by the heating tube 312, the substrate that is placed on the support panel 318 will be heated also; and as soon as the temperature sensor 314 detected that the temperature of the temperature control module 31 had reached a predetermined temperature, a thermostatic liquid of the predetermined temperature will be guided to flow into the constant temperature plate 317 for maintaining the temperature of the temperature control module 31 at the predetermined temperature. On the other hand, when the temperature sensor 314 detected that the temperature of the temperature control module 31 is below the predetermined temperature, the heating tube 312 will be activated again to heat the support panel 318 until the temperature of the temperature control module 31 is raised to the predetermined temperature.
S2: enabling the first image capturing module 410 to search a wafer placed on the carrier 200 for locating the positions of the plural dies of the wafer, whereas each of the die has a base temperature, and in this embodiment, the base temperature is room temperature that is smaller than the aforesaid predetermined temperature.
S3: According to the images captured by the first image capturing module 410, selectively enabling the rotation module 201 to rotate the carrier 200 by an angle, or enabling the X-axis mover 202 to move the carrier in the X-axis direction by a first distance, or enabling the Y-axis mover 203 to move the carrier in the Y-axis direction by a first distance. As shown in FIG. 5, by the cooperation of the X-axis move module 43, Z-axis alignment module 42, and the Y-axis move module 40, the pick-and-place module 41 can be moved and placed on top of the workbench 20. As soon as the pick-and-place module 41 is moved to the top of the dies that are to be processed, the die will be pushed and ejected by the die ejection module 21 for allowing the plural suction nozzles 414 to suck and fetch their corresponding dies sequentially.
S4: As shown in FIG. 6, after picking up the dies, the pick-and-place module 41 is driven to move toward the heating/cooling unit 3, i.e. the pick-and-place module 41 will first be driven to move upward along the Z-axis direction by a distance, and then moved in the Y-axis direction toward the heating/cooling unit 3; and during the moving of the pick-and-place module 41, the second image capturing module 5 is enabled to capture images relating to the bottom view of the dies held in their respectively suction nozzles 414, and thereby, if there is any of those dies that is not aligned correctly, its corresponding angular alignment elements 415 will be activated for adjusting the positioning of the die by rotating the relating suction nozzle 414 by an angle. In short, the angular alignment element is enabled to correct the alignment of the die according to the imaging of the second image capturing module.
S5: moving a pick-and-place module 41 on top of a substrate which has already been heated to the predetermined temperature while enabling the pick-and-place module 41 to align correctly with the substrate according to the imaging of the first image capturing module 410.
S6: as soon as the pick-and-place module 41 is moved to the position aligned with the substrate, the pick-and-place module 41 is driven to move downward in the Z-axis direction by a distance so as to allow the pick-and-place module 41 to bond the dies on the substrate by exerting a downward pushing force on the dies, as shown in FIG. 7.
S7: as shown in FIG. 3, the temperature control module 31 is enabled to perform a cooling process upon the substrate with bonded dies by enabling a cooling fluid to flow inside the support panel 318 so as to cool down the substrate, and simultaneously, another temperature control module 31 is activated for heating up another substrate that is to be used in another die bonding process.
S8: enabling the Y-axis move module 30 to move the temperature control module along with the substrate with bonded dies to a loading/unloading position, while activating the Y-axis move module 30 also to move another temperature control module 31 with preheated substrate to the position under the pick-and-place module 41 for another die bonding process.

To sum up, in the die bonding method, the substrate is preheated to a predetermined temperature, and then dies of room temperature are placed on the preheated substrate correctly according to the alignment of the first and the second image capturing modules. Thereafter, the correctly aligned dies can be bonded to the substrate by the downward pressure from the pick-and-place module. Thus, the die bonding method is an efficient manufacture method without complicated process and can be completed in a comparatively shorter time.

By the present disclosure, dies can simply be picked up and placed directly on a substrate, and then they are ready to be bonded to the substrate. Moreover, by the plural suction nozzles in the pick-and-place module, the pick-and-place module is able to fetch a plurality of dies from the die supplier at once, so that the overall time spent in the picking up and placing dies can be reduced. In addition, there can be two platforms used simultaneously in the present disclosure, by that operationally when one of the two platform is performing a die bonding process, another one can be cooling down and prepared for carrying another substrate to be bonded with dies. Consequently, the process time is reduced.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

1. A die bonding method, comprising the steps of:
heating a substrate to a predetermined temperature;
picking up at least one die;
placing and bonding the at least one die to the substrate;
cooling the substrate with the bonded die; and
moving the substrate with the bonded die to a loading/unloading position while enabling another substrate to be heated to the predetermined temperature for repeating the aforesaid steps.

2. The die bonding method of claim 1, wherein the predetermined temperature is ranged between 85° C. and 200° C.

3. The die bonding method of claim 1, wherein the heating of the substrate to the predetermined temperature is enabled by the use of a heating/cooling unit, while the cooling of the substrate with the bonded die is also enabled by the use of the heating/cooling unit.

4. The die bonding method of claim 1, wherein the at least one die is provided from a die supplier.

5. The die bonding method of claim 4, wherein the die supplier is a device having a plurality of dies disposed therein and is a device capable of selectively enabling the at least one die to rotate by an angle, to move in an X-axis direction by a first distance, and/or to move in a Y-axis direction by a second distance.

6. The die bonding method of claim 1, wherein the steps for picking up and placing and bonding the at least one die are performed by the use of a die bonder.

7. The die bonding method of claim 1, further comprising the step of:
using a first image capturing module to capture images of the at least one die to be used in the step for picking up the at least one die.

8. The die bonding method of claim 7, wherein the first image capturing module is enabled to capture image of the substrate to be used for adjusting the position of the at least one die and the position of the substrate in the placing and bonding of the at least one die to the substrate.

9. The die bonding method of claim 1, wherein images relating to the bottom view of the at least one die are captured by a second image capturing module so as to be used for adjusting the position of the at least one die.

10. A die bonding apparatus, comprising:
a platform;
a die supplier, disposed at an end of the platform;
a heating/cooling unit, disposed at another end of the platform other than the one corresponding to the die supplier, wherein the heating/cooling unit further includes:
at least one temperature control module; and
at least one Y-axis move module, where the at least one temperature control module is mounted to the at least one Y-axis move module; and
a die bonder, disposed on top of the platform while allowing the same to move between the die supplier and the heating/cooling unit.

11. (canceled)

12. The die bonding apparatus of claim 10, wherein each of the at least one temperature control module further comprises: a support panel, a constant temperature plate, a temperature sensor; the support panel is further configured with at least one cooling fluid inflowing tube, at least one cooling fluid discharging tube, at least one heating tube; the temperature sensor is arranged at a position between the support panel and the constant temperature plate; and the constant temperature plate is configured with a thermostatic liquid inflowing tube and a thermostatic liquid discharging tube.

13. The die bonding apparatus of claim 12, wherein each of the at least one temperature control module further comprises: at least one bracket, each being arranged at a position between the support panel and the constant temperature plate; and there is further a heat insulation plate attached to the bottom of the support panel.

14. The die bonding apparatus of claim 10, wherein the die bonder further comprises: a Y-axis move module, a pick-and-place module, a Z-axis alignment module, and an X-axis move module; the Y-axis move module is mounted to the two sides of the platform; the Z-axis alignment module is coupled to the pick-and-place module, and the X-axis move module is coupled to the pick-and-place module and the Y-axis move module.

15. The die bonding apparatus of claim 14, wherein the pick-and-place module further comprises: a plurality of suction nozzles, a plurality of angular alignment elements, a plurality of vacuum adapters and a plurality of adjustable pressurizers; the plural suction nozzles are arranged coupling to the plural angular alignment elements in respective, the plural vacuum adapters are arranged coupling to the plural suction nozzles in respective while allowing the plural pressurizers to couple respectively to the plural vacuum adapters.

16. The die bonding apparatus of claim 10, further comprising:
a first image capturing module, arranged at the pick-and-place module.

17. The die bonding apparatus of claim 10, further comprising:
a second image capturing module, arranged above the platform at a position between the die supplier and the heating/cooling unit.

18. The die bonding apparatus of claim 10, wherein the die supplier further comprises: a workbench; and a die ejection module, mounted to a bottom end of the workbench.

19. The die bonding apparatus of claim 18, wherein the workbench is configured with a carrier, a rotation module, an X-axis mover and a Y-axis mover in a manner that the carrier is mounted to a top end of the rotation module, while the X-axis mover and the Y-axis mover are mounted to a bottom end of the carrier.
